(19) United States
(12) Patent Application Publication
(10) Pub. No.: US 2022/0415742 A1
(43) Pub. Date: Dec. 29, 2022

(54) MICROELECTRONIC ASSEMBLIES HAVING DIES WITH BACKSIDE BACK-END-OF-LINE HEATER TRACES

(71) Applicant: Intel Corporation, Santa Clara, CA (US)

(72) Inventors: Bijoyraj Sahu, Portland, OR (US); Tolga Acikalin, San Jose, CA (US); Anand Haridass, Bangalore (IN); Vikrant Thigle, Bangalore (IN)

(73) Assignee: Intel Corporation, Santa Clara, CA (US)

(21) Appl. No.: 17/356,239

(22) Filed: Jun. 23, 2021

(51) Int. Cl. H01L 23/34; H01L 23/36; H01L 23/48

(52) U.S. Cl. CPC H01L 23/345; H01L 23/36; H01L 23/481

(57) ABSTRACT

Microelectronic assemblies, related devices and methods, are disclosed herein. In some embodiments, a microelectronic assembly may include a package substrate, and a die, electrically coupled to the package substrate, including a silicon substrate having a first surface and an opposing second surface; a device layer at the first surface of the silicon substrate; and a dielectric layer, having a heater trace, at the second surface of the silicon substrate.

### BACKGROUND

For reliable operation, integrated circuit (IC) packages typically must be maintained within a “safe” temperature range. Some IC packages that are required to operate at temperatures below the safe range may include a heat source to maintain IC devices within the safe range.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1A is a side, cross-sectional view of an example microelectronic assembly, in accordance with various embodiments.

FIG. 1B is a simplified schematic showing a side, cross-sectional view of a portion of a conventional power delivery network configuration.

FIG. 1C is a simplified schematic showing a side, cross-sectional view of a portion of an exemplary backside power delivery network configuration.

FIGS. 2A-2E are top views of example heater traces, in accordance with various embodiments.

FIG. 3 is a side, cross-sectional view of another example microelectronic assembly, in accordance with various embodiments.

FIG. 4 is a side, cross-sectional view of another example microelectronic assembly, in accordance with various embodiments.

FIG. 5 is a side, cross-sectional view of another example microelectronic assembly, in accordance with various embodiments.

FIG. 6 is a side, cross-sectional view of another example microelectronic assembly, in accordance with various embodiments.

FIG. 7 is a side, cross-sectional view of another example microelectronic assembly, in accordance with various embodiments.

FIG. 8 is a top view of a wafer and dies that may be included in a microelectronic assembly, in accordance with any of the embodiments disclosed herein.

FIG. 9 is a cross-sectional side view of an IC device that may be included in a microelectronic assembly, in accordance with any of the embodiments disclosed herein.

FIG. 10 is a cross-sectional side view of an IC device assembly that may include a microelectronic assembly, in accordance with any of the embodiments disclosed herein.

FIG. 11 is a block diagram of an example electrical device that may include a microelectronic assembly, in accordance with any of the embodiments disclosed herein.

### DETAILED DESCRIPTION

Microelectronic assemblies, and related apparatuses and methods for heating devices within a die, are disclosed herein. For example, in some embodiments, a microelectronic assembly may include a package substrate, and a die, electrically coupled to the package substrate, including a silicon substrate having a first surface and an opposing second surface; a device layer at the first surface of the silicon substrate; and a dielectric layer, having a heater trace, at the second surface of the silicon substrate.

The edge computing market is growing significantly. Developing low-cost, high performance, and reliable edge computing systems is becoming an industry wide trend. A key requirement for edge devices is reliable operation at sub-zero temperatures (e.g., operation at a silicon juncture temperature (Tj) of less than zero (0) degrees Celsius). Edge computing systems typically include IC components that have a safe Tj temperature range between 0 degrees Celsius and 125 degrees Celsius. When the edge devices are located in cold climates (e.g., an ambient temperature range between −45 degrees Celsius and 85 degrees Celsius), the IC components may operate at sub-zero temperatures and outside of the safe Tj temperature range.

Some conventional IC devices may include a heating apparatus in order to transport heat to an electronic component or a device within the electronic component (e.g., a transistor within a die) during operation for cold boots or for operation at cold temperatures. Typically, a heating apparatus is in thermal contact with an electronic component and transfers heat via thermal conduction. Conventional solutions include indirectly heating the device within the electronic component by placing a heating apparatus on a package substrate, on an interposer, or on an electronic device, such that, the device is heated via thermal conduction through the package substrate, the interposer, and/or the electronic device. This indirect heating requires more heating power as the entire system is heated and maintained within the safe temperature range. A more efficient IC device heating apparatus may be desirable. The microelectronic assemblies disclosed herein may be particularly advantageous for applications in computers, tablets, industrial robots, consumer electronics (e.g., wearable devices), and sensor devices used to monitor and collect data in remote locations that operate in cold climates.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die” and an “IC die.” The terms “top” and “bottom” may be used herein to explain various features of the drawings, but these terms are simply for ease of discussion, and do not imply a desired or required orientation. As used herein, the term “insulating” means “electrically insulating,” unless otherwise specified. Throughout the specification, and in the claims, the term “coupled” means a direct or indirect connection, such as a direct electrical, mechanical, or magnetic connection between the things that are connected or an indirect connection, through one or more passive or active intermediary devices. The meaning of “a,” “an,” and “the” include plural references. The meaning of “in” includes “in” and “on.”

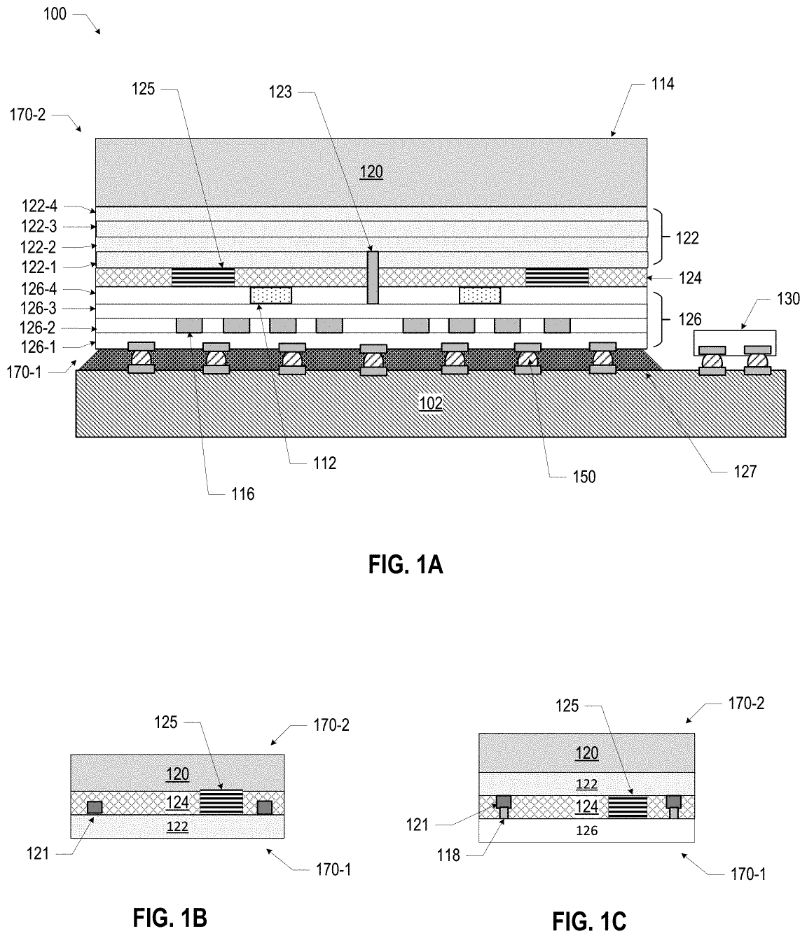

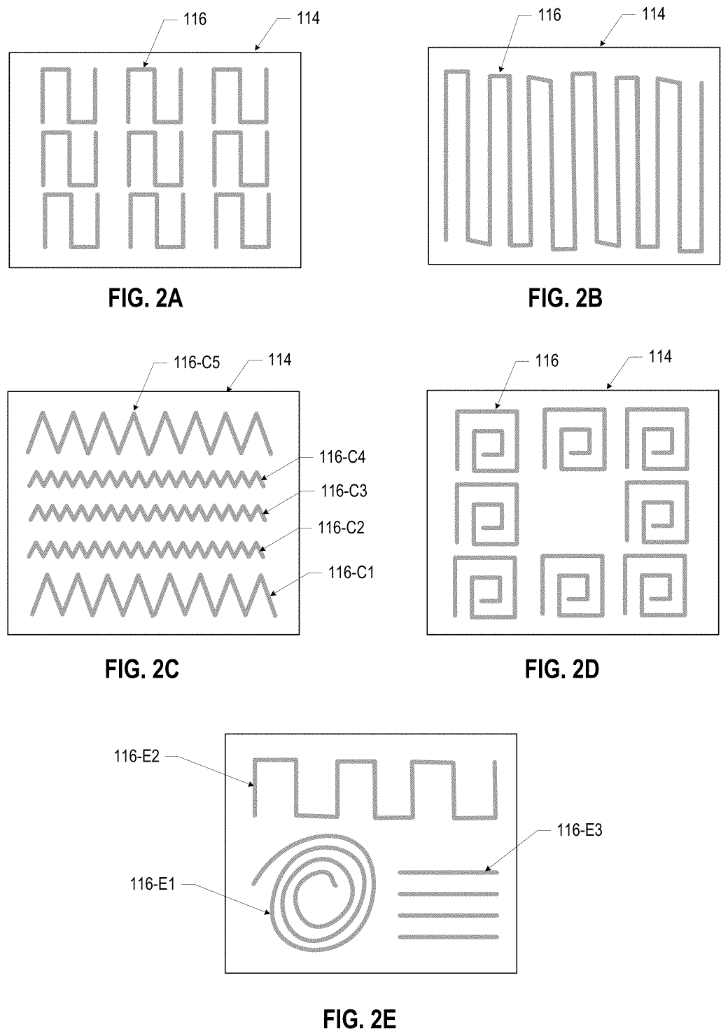

When used to describe a range of dimensions, the phrase “between X and V” represents a range that includes X and Y. For convenience, the phrase “FIG. 1” may be used to refer to the collection of drawings of FIGS. 1A-1C, the phrase “FIG. 2” may be used to refer to the collection of drawings of FIGS. 2A-2E, etc. Although certain elements may be referred to in the singular herein, such elements may include multiple sub-elements. For example, “an insulating material” may include one or more insulating materials. As used herein, a “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket, or portion of a conductive line or via).

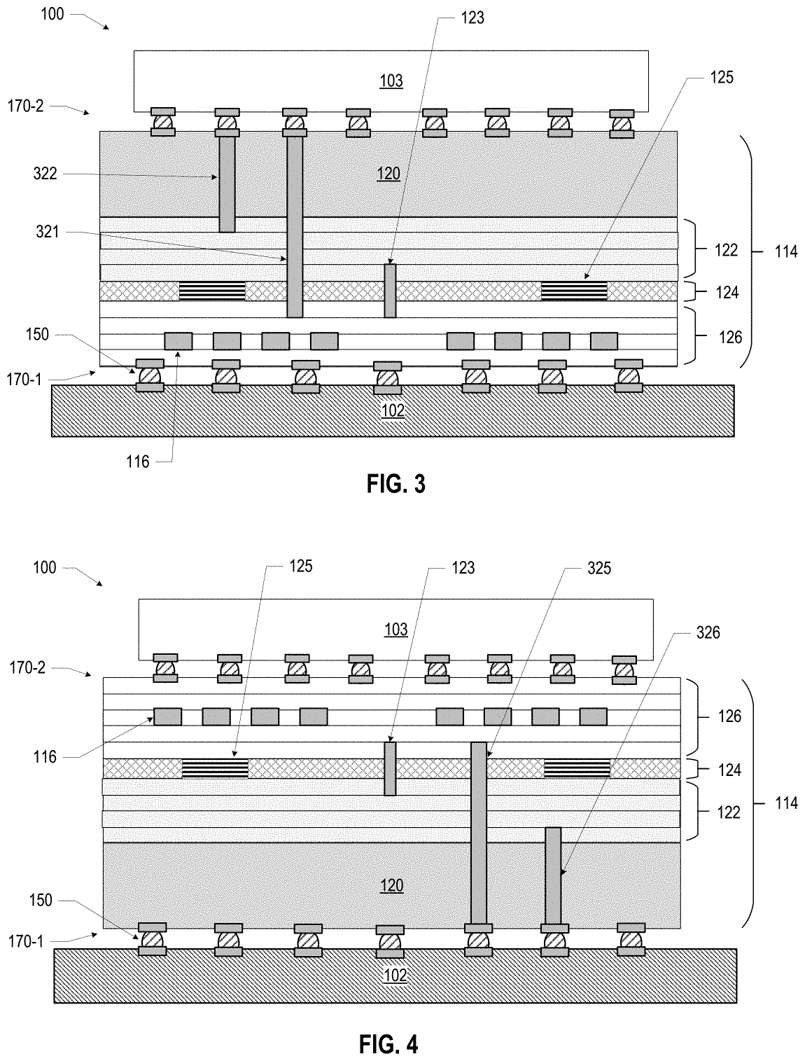

FIG. 1A is a side, cross-sectional view of an example microelectronic assembly, in accordance with various embodiments. The microelectronic assembly 100 may include a die 114 having a backside power delivery network (backside PDN) configuration coupled to a package substrate 102. The backside PDN of the die 114 may include a backside-BEOL 126 having one or more heater traces 116 to provide heat to the die 114 for operation within a desired temperature range. For example, the die 114 may include a heater trace 116 on a backside-BEOL layer 126 coupled to a power source on the package substrate 102. The power source may include a power source and a ground source, or a first power source and a second power source. When power is provided to the heater trace 116, the heater trace 116 generates heats. As used herein, the backside-BEOL 126 may be referred to as “layer 126,” “dielectric layer 126,” or “heater trace dielectric layer 126.” FIG. 1B is a simplified schematic showing a side, cross-sectional view of a portion of a conventional PDN configuration. The conventional PDN includes a conventional or standard back-end-of-the-line (standard-BEOL) 122 at a first side 170-1 and directly connected to a FEOL 124. The FEOL 124 includes devices 125, such as transistors. As used herein, the FEOL 124 may be referred to as a “device layer 124.” As used herein, the standard-BEOL 122 may be referred to as “layer 122” or “dielectric layer 122.” The conventional PDN further includes a silicon substrate 120 at a second side 170-2, where the device layer 124 is between the silicon substrate 120 and the layer 122. As used herein, the silicon substrate 120 may be referred to as “substrate 120.” In some embodiments, the conventional PDN may include buried power rails (BPRs) 121 (e.g., power source (VDD) and ground source (VSS)) to locally supply power to devices in the device layer 124. FIG. 1C is a simplified schematic showing a side, cross-sectional view of a portion of an exemplary backside PDN configuration. As shown in FIG. 1C, a backside PDN may include a backside-BEOL 126 at a first side 170-1, a device layer 124 on the backside-BEOL 126, a layer 122 on the device layer 124, and a silicon substrate 120 on the layer 122 (e.g., at a second side 170-2). The backside PDN may further include BPRs 121 and micro-through silicon vias (μTSVs) 118. The μTSVs connect BPRs 121 in the backside-BEOL 126 to devices 125 in the device layer 124 via the layer 122. Although FIG. 1C shows a backside PDN having a particular configuration, a backside PDN may have a different configuration and may have different layers, for example, as described below with reference to FIGS. 3 and 4.

As shown in FIG. 1A, the die 114 may have a BEOL configuration with a device layer 124 between two multi-layer stacks (e.g., device layer 124 and backside-BEOL 126). The backside-BEOL 126 and the layer 122 may include a plurality of layers (e.g., 126-1, 126-2, 126-3, 126-4 and 122-1, 122-2, 122-3, 122-4, respectively) that include an insulating material formed in multiple layers and multiple conductive pathways (not shown) formed through the insulating material. The die 114 may further include a μTSV 123 that electrically couples the conductive pathways in the backside-BEOL 126 and the conductive pathways in the dielectric layer 122. In particular, the backside PDN may include a backside-BEOL 126 at a first surface 170-1, a device layer 124 on the backside-BEOL 126, a layer 122 on the device layer 124, and a silicon substrate 120 on the layer 122. In some embodiments, the silicon substrate 120 may be omitted. In such embodiments, the silicon substrate 120 may be removed using any suitable technique, including, for example, mechanical grinding. As shown in FIG. 1A, the die 114 may further include a heater trace 116 in the backside-BEOL 126. The heater trace 116 may be used to provide heating to the die 114, for example, to the devices within the device layer 124. The device layer 124 may include active and passive devices (e.g., transistors, diodes, resistors, inductors, and capacitors, among others). In some embodiments, the device layer 124 may include one or more device layers including transistors (e.g., as discussed below with reference to FIG. 9). For example, the device layer 124 may include first and second transistors, where the first transistor may be a p-type metal oxide semiconductor (PMOS) and the second transistor may be an n-type metal oxide semiconductor (NMOS). The backside-BEOL 126 may include one or more heater traces 116 proximate to the devices 125 of the device layer 124 and may provide heat particularly to the devices 125 in the device layer 124 and generally to the die 114 as well as to other microelectronic components coupled to the die 114 directly (e.g., microelectronic component 103 in FIG. 3) or indirectly (e.g., heater control device 130). In some embodiments, a distance of the heater traces 116 from the devices 125 may be between 0.5 microns and 2 millimeters. The heater traces 116 may be formed of an electrically conductive material (e.g., a metal, such as copper). The heater traces 116 may be coupled to a power source. In some embodiments, the heater trace 116 may include a first end coupled to a power source (not shown) in the package substrate 102 and a second end coupled to a ground source (not shown) in the package substrate 102 via first level interconnects (FLIs) 150 between the first surface 170-1 of the die 114 and the package substrate 102. The heater trace 116 may be connected to a voltage differential that causes current to flow through the heater trace 116. In some embodiments, the heater trace 116 may include a first end coupled to a first power source (e.g., a higher power source) (not shown) in the package substrate 102 and a second end coupled to a second power source (e.g., a lower power source) (not shown) in the package substrate 102 via first level interconnects (FLIs) 150 between the first surface 170-1 of the die 114 and the package substrate 102. The heater traces 116 may be arranged such that, when power is applied to the heater traces 116 via the FLIs 150, the heater traces 116 generate heat that may be conducted throughout the die 114. The amount of power provided to the heater traces 116 may depend on the particular temperature to be achieved to heat the devices 125 and/or the die 114 for operation within a safe temperature range. In some embodiments, a safe Tj range for a die 114 and/or a device 125 may be between 0 degrees Celsius and 125 degrees Celsius. In some embodiments, a safe Tj range may be between 15 degrees Celsius and 60 degrees Celsius. The desired temperature or temperature range may depend on the type and configuration of the devices 125, the die 114, and/or the microelectronic assembly 100, as well as the arrangement of the heater traces 116, and thermal constraints within the die 114. In some embodiments, the heater traces 116 may be shaped and arranged based on an available power source (e.g., a high current, low voltage power source (e.g., a heater trace may be formed to be thicker, wider, and/or longer to withstand a high current), a high voltage, low current power source (e.g., a heater trace may be arranged further apart from an adjacent heater trace, may be arranged further apart from a heater trace on an adjacent layer, and/or may be insulated with a material having improved dielectric properties to withstand a high voltage), or a combination of a high current, low voltage and a high voltage, low current power source (e.g., a heater trace may be formed and arranged to optimize its ability to withstand a high current and a high voltage).—In some embodiments, the heater traces 116 may be in a same layer of the backside-BEOL 126 In some embodiments, the heater traces 116 may be in different layers of the backside-BEOL 126. In some embodiments, one or more heater traces 116 may be coupled to a single power source such that power may be provided to multiple heater traces 116 simultaneously. In some embodiments, each individual heater trace 116 may be coupled to an individual power source such that only selected areas of the die 114 may be heated. For example, different ones of the heater traces 116 may be provided with power to generate heat in different regions of the die 114 in order to achieve a uniform temperature profile in the die 114 or the heat a specific region of the die 114 (e.g., a device 125). The specific number of heater traces 116 shown in FIG. 1A is simply illustrative, and more or fewer heater traces 116 may be included in the die 114. Additionally, the specific arrangement of the heater traces 116 shown in FIG. 1A is simply illustrative, and any suitable arrangement may be used.

Locating heaters (e.g., heater traces 116) proximate to the devices 125 in the die 114 has multiple benefits. The required heat to bring the temperature of devices to the desired temperature at cold operating ambient temperatures is minimized. The overall power consumption of a microelectronic assembly 100 is reduced, which is especially important for many node and distributed internet of things applications, where the microelectronic assembly may be operating from a battery or renewable energy sources. The localized heating achieved by the heater traces 116 is likely to decrease the amount of time and power required to bring the devices 125 and/or the die 114 to a desired temperature. Typically, after a cold boot, the power consumption of the microelectronic assembly 100 is sufficient to maintain the device temperature at or above the desired minimum operational temperature specification. However, if this power is insufficient, local heater traces 116 may provide additional heating. Further, the heater traces 116 may significantly increase the reliability lifetime of a microelectronic assembly 100. The heater traces 116 may provide heat to reduce the temperature variations (e.g., cycles) experienced by the microelectronic assembly 100 to maintain the operating temperature and increase the reliability lifetime.

The backside-BEOL 126 may further include one or more temperature sensor traces 112. A temperature sensor trace 112 may be formed of an electrically conductive material (e.g., a metal, such as copper) whose electrical resistance changes as a function of the equivalent temperature of the temperature sensor trace 112. Safe temperature range for a die 114 between −40 degrees Celsius and 125 degrees Celsius. As used herein, the “equivalent temperature” may represent a weighted average of the temperature of a temperature sensor trace 112; for example, if 90% of the length of a constant width temperature sensor trace 112 is 10 degrees and the remaining 10% of the length of the temperature sensor trace 113 is 20 degrees, the equivalent temperature for the temperature sensor trace 113 may be 11 degrees. The function relating electrical resistance and equivalent temperature may be given by:

R=Rref(1+α(T−Tref))

where R is the electrical resistance of the temperature sensor trace 112 at the equivalent temperature T, Rref is a reference electrical resistance of the temperature sensor trace 112 at a reference temperature Tref, and alpha is the temperature coefficient of resistance for the material forming the temperature sensor trace 112. The values of alpha, Rref, and Tref may be experimentally determined or may be known in the art, and are accordingly not discussed further herein. When alpha, Rref, and Tref are known for a particular temperature sensor trace 112, a measurement of the electrical resistance R of the temperature sensor trace 112 may enable the equivalent temperature T of the temperature sensor trace 112 to be determined in accordance with the above function. The values of .alpha., Rref, and Tref may be stored in a memory device (e.g., in a lookup table) and may be accessed as desired. In some embodiments, functions other than the function given above may more accurately describe the relationship between electrical resistance R and equivalent temperature T of a temperature sensor trace 112 (e.g., as determined experimentally); in such embodiments, the parameters of the more accurate function may be stored in a memory device (e.g., in a lookup table) and used to determine the equivalent temperature T based on the electrical resistance R. In some embodiments, the temperature sensor traces 112 may be included in the layer 122. In some embodiments, the temperature data provided by the resistance of the temperature sensor traces 112 may be used by a heater control device 130 when providing power to the heater traces 116 in order to achieve particular temperatures at one or more locations in the die 114. In some embodiments, the heater traces 116 and/or the temperature sensor traces 112 in the die 114 may have connection terminals (not shown) exposed at the first surface 170-1 of the die 114 at which a heater control device 130 may make electrical contact with the heater traces 116 (to provide power to the heater traces 116 to cause the heater traces 116 to generate heat) and/or with the temperature sensor traces 112 (to measure their electrical resistance and determine their equivalent temperatures). For example, the temperature sensor traces 112 of the die 114 may be used to measure the equivalent temperature near the devices 125, and that temperature may be provided to a feedback loop in the heater control device 130 to control the amount of power provided to the heater traces 116 to achieve a desired temperature at the devices 125. In another example, the temperature sensor traces 112 may be used to measure the equivalent temperature of the die 114, and that temperature may be provided to a feedback loop in the heater control device 130 to control the amount of power provided to the heater traces 116 to achieve a desired temperature of the die 114. The “amount” of power may be proportional to the duty cycle settings of a pulse width modulated (PWM) current or voltage signal, the RMS value of an AC current or voltage signal, a DC value of a current or voltage signal, or a combination thereof. The feedback loop may also be used to ensure that other portions of the die 114 do not exceed a maximum temperature and/or the temperature across the die 114 is relatively uniform to mitigate any mechanical failures that may occur as a result of operating outside of the desired temperature range. In some embodiments, the heater control device 130 may be configured to measure the resistance of the temperature sensor trace 112 and determine the equivalent temperature of the temperature sensor trace 112. The heater control device 130 may control the power provided to the heater traces 116 based on the equivalent temperature (e.g., increasing the power when the equivalent temperature is below a desired reflow temperature, and vice versa). The heater control device 130 may be configured to limit the heat generated by the heater traces 116 (e.g., amount of power provided) to avoid overheating the die 114. The specific number of temperature sensor traces 112 shown in FIG. 1A is simply illustrative, and more or fewer temperature sensor traces 112 may be included in the die 114. Additionally, the specific arrangement of temperature sensor traces 112 shown in FIG. 1A is simply illustrative, and any suitable arrangement may be used. In some embodiments, no temperature sensor traces 112 may be included in the die 114. In some embodiments, the heater control device 130 may be incorporated in or coupled to the package substrate by FLIs 150, as shown in FIG. 1A, where the heater control device 130 is coupled to the heater traces 116 via conductive pathways (not shown) in the package substrate 102. In some embodiments, the heater control device 130 may be incorporated in or coupled to the die 114. The heater control device 130 may be implemented using any controller device and technique known in the art (e.g., a microcontroller configured with feedback). In some embodiments, no heater control device 130 may be included. In some embodiments, the die 114 may further include digital temperature sensors (DTS) or thermal diodes for measuring a temperature of the die.

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). Example structures that may be included in the dies 114 disclosed herein are discussed below with reference to FIG. 9. The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked).

The package substrate 102 may include an insulating material (e.g., a dielectric material formed in multiple layers, as known in the art) and one or more conductive pathways to route power, ground, and signals through the dielectric material (e.g., including conductive traces and/or conductive vias, as shown). In some embodiments, the insulating material of the package substrate 102 may be a dielectric material, such as an organic dielectric material, a fire retardant grade 4 material (FR-4), BT resin, polyimide materials, glass reinforced epoxy matrix materials, organic dielectrics with inorganic fillers or low-k and ultra low-k dielectric (e.g., carbon-doped dielectrics, fluorine-doped dielectrics, porous dielectrics, and organic polymeric dielectrics). In particular, when the package substrate 102 is formed using standard printed circuit board (PCB) processes, the package substrate 102 may include FR-4, and the conductive pathways in the package substrate 102 may be formed by patterned sheets of copper separated by build-up layers of the FR-4. The conductive pathways in the package substrate 102 may be bordered by liner materials, such as adhesion liners and/or barrier liners, as suitable. In some embodiments, the package substrate 102 may be formed using a lithographically defined via packaging process. In some embodiments, the package substrate 102 may be manufactured using standard organic package manufacturing processes, and thus the package substrate 102 may take the form of an organic package. In some embodiments, the package substrate 102 may be a set of redistribution layers formed on a panel carrier by laminating or spinning on a dielectric material, and creating conductive vias and lines by laser drilling and plating. In some embodiments, the package substrate 102 may be formed on a removable carrier using any suitable technique, such as a redistribution layer technique. Any method known in the art for fabrication of the package substrate 102 may be used, and for the sake of brevity, such methods will not be discussed in further detail herein.

In some embodiments, the package substrate 102 may be a lower density medium and the die 114 may be a higher density medium or have an area with a higher density medium. As used herein, the term “lower density” and “higher density” are relative terms indicating that the conductive pathways (e.g., including conductive interconnects, conductive lines, and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a PCB manufactured using a standard PCB process (e.g., a standard subtractive process using etch chemistry to remove areas of unwanted copper, and with coarse vertical interconnect features formed by a standard laser process). In other embodiments, the higher density medium may be manufactured using semiconductor fabrication process, such as a single damascene process or a dual damascene process.

The FLIs 150 disclosed herein may take any suitable form. In some embodiments, the FLIs 150 may include solder (e.g., solder bumps or balls that are subject to a thermal reflow to form the interconnects). In some embodiments, the FLIs 150 may include an anisotropic conductive material, such as an anisotropic conductive film or an anisotropic conductive paste. An anisotropic conductive material may include conductive materials dispersed in a non-conductive material.

The microelectronic assembly 100 of FIG. 1A may also include an underfill material 127. In some embodiments, the underfill material 127 may extend between the die 114 and the package substrate 102 around the associated FLIs 150. The underfill material 127 may be an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering the die 114 to the package substrate 102 when forming the FLIs 150, and then polymerizes and encapsulates the FLIs 150. The underfill material 127 may be selected to have a coefficient of thermal expansion (CTE) that may mitigate or minimize the stress between the die 114 and the package substrate 102 arising from uneven thermal expansion in the microelectronic assembly 100. In some embodiments, the CTE of the underfill material 127 may have a value that is intermediate to the CTE of the package substrate 102 (e.g., the CTE of the dielectric material of the package substrate 102) and a CTE of the die 114.

The microelectronic assembly 100 of FIG. 1A may also include a circuit board (not shown). The package substrate 102 may be coupled to the circuit board by second-level interconnects at the bottom surface of the package substrate 102. The second-level interconnects may be any suitable second-level interconnects, including solder balls for a ball grid array arrangement, pins in a pin grid array arrangement or lands in a land grid array arrangement. The circuit board may be a motherboard, for example, and may have other components attached to it. The circuit board may include conductive pathways and other conductive contacts for routing power, ground, and signals through the circuit board, as known in the art. In some embodiments, the second-level interconnects may not couple the package substrate 102 to a circuit board, but may instead couple the package substrate 102 to another IC package, an interposer, or any other suitable component. In some embodiments, the multi-layer die subassembly may not be coupled to a package substrate 102, but may instead be coupled to a circuit board, such as a PCB.

Many of the elements of the microelectronic assembly 100 of FIG. 1A are included in other ones of the accompanying figures; the discussion of these elements is not repeated when discussing these figures, and any of these elements may take any of the forms disclosed herein. Further, a number of elements are illustrated in FIG. 1A as included in the microelectronic assembly 100, but a number of these elements may not be present in a microelectronic assembly 100. For example, in various embodiments, the heater control device 130, the temperature sensor traces 112, the BPRs 121, and the underfill material 127 may not be included. In some embodiments, the device layer 124 and/or the dielectric layer 122 may be omitted (e.g., when the die 114 is passive), such that the heater traces 116 may heat the die 114 and other microelectronic components coupled directly and indirectly to the die 114.

FIGS. 2A-2E are top views of example heater traces, in accordance with various embodiments. The heater traces 116 may have any suitable shape, dimensions, and arrangement. In some embodiments, the heater traces 116 may be formed and patterned to optimize conductive heating of the devices 125 and/or the die 114. For example, the heater traces 116 may be fabricated using backside-BEOL processes, as known in the art. FIG. 2A shows a schematic of example heater traces having a serpentine pattern (e.g., an up, down block pattern) where nine individual heater traces 116 are arranged in a grid array on the die 114. In some embodiments, one or more of the nine individual heater traces 116 may be coupled together. FIG. 2B shows a schematic of an example heater trace having a serpentine pattern where an individual heater trace 116 is on the die 114. FIG. 2C shows a schematic of example heater traces having a zigzag pattern where five individual heater traces 116 are arranged in rows on the die 114. As shown in FIG. 2C two heater traces 116-C1, 116-05 have a first pattern and three heater traces 116-C2, 116-C3, 116-C4 have a second heater pattern. The first and second heater patterns may provide more or less heat to an area of the die 114. The FIG. 2D shows a schematic of example heater traces having a block spiral pattern where eight individual heater traces 116 are arranged in a ring on the die 114 (e.g., along the outer perimeter of the die 114). FIG. 2E shows a schematic of example heater traces having three different shapes, including a spiral-shaped heater trace 116-E1, a serpentine-shaped heater trace 116-E2, and four straight lined heater traces 116-E3, arranged to provide different amounts of heat to different areas of the die 114. In some embodiments, the heater traces 116 may be arranged within the backside-BEOL 126 of the die 114 to include areas covered by the heater traces 116 and areas not covered by the heater traces 116. Although FIGS. 2A-2E show particular numbers, shapes, sizes, and arrangements of heater traces 116, a die may have any suitable number, shape, size, and arrangement of heater traces 116.

FIG. 3 is a side, cross-sectional view of another example microelectronic assembly, in accordance with various embodiments. The microelectronic assembly 100 may include a die 114 having a backside PDN configuration that includes a backside-BEOL 126 at a first surface 170-1, a device layer 124 on the backside-BEOL 126, a layer 122 on the device layer 124, and a silicon substrate 120 on the layer 122. The backside PDN of the die 114 may include a backside-BEOL 126 having one or more heater traces 116 to provide heat to the die 114 for operation within a desired temperature range and/or to provide heat to the devices 125 on the device layer 124. The backside PDN may include a μTSV 123. The die 114 may be coupled to a package substrate 102 at a first surface 170-1 and coupled to a microelectronic component 103 at a second surface 170-2 (i.e., at the silicon substrate 120). The microelectronic assembly 100 may further include a first TSV 321 coupling the backside-BEOL 126 to the microelectronic component 103 and a second TSV 322 coupling the layer 122 to the microelectronic component 103. For example, the first and second TSVs 321, 322 may provide signals and/or power to the die 114 and/or the microelectronic component 103. In some embodiments, a microelectronic component 103 may include an IC die (packaged or unpackaged) or a stack of an IC dies (e.g., a high-bandwidth memory dies stack). In some embodiments, a microelectronic component 103 may include an interposer. The heater traces 116 may be coupled to a power source (not shown) in the package substrate 102 via FLIs 150 between the first surface 170-1 of the die 114 and the package substrate 102. The heater traces 116 may be arranged such that, when power is applied to the heater traces 116, the heater traces 116 generate heat that may be conducted throughout the die 114. In some embodiments, the device layer 124 and/or the layer 122 may be omitted (e.g., when the die 114 is passive), such that the heater traces 116 may heat the die 114 and microelectronic component 103. In some embodiments, the silicon substrate 120 may be omitted, (e.g., such that the layer 122 is at the second surface 170-2 of the die 114) and the microelectronic component 103 may be coupled to the layer 122 at the second surface 170-2 of the die 114. In such embodiments, the silicon substrate 120 may be removed using any suitable technique, including, for example, mechanical grinding.

FIG. 4 is a side, cross-sectional view of another example microelectronic assembly, in accordance with various embodiments. The microelectronic assembly 100 may include a die 114 having a backside PDN configuration that includes a silicon substrate 120 at a first surface 170-1, a layer 122 on the silicon substrate 120, a device layer 124 on the layer 122, and a backside-BEOL 126 on the device layer 124. The backside PDN of the die 114 may include one or more heater traces 116 on the backside-BEOL 126 to provide heat to the die 114 for operation within a desired temperature range and/or to provide heat to the devices 125 on the device layer 124. The backside PDN may include a μTSV 123. The die 114 may be coupled to a package substrate 102 at the first surface 170-1 and coupled to a microelectronic component 103 at the second surface 170-2 (i.e., at the backside-BEOL 126). The microelectronic assembly 100 may further include a first TSV 325 coupling the backside-BEOL 126 to the package substrate 102 and a second TSV 326 coupling the layer 122 to the package substrate. For example, the first and second TSVs 325, 326 may provide signals and/or power to the die 114 and/or the microelectronic component 103. The heater traces 116 may be coupled to a power source (not shown) in the package substrate 102 via the first and second TSVs 325, 326 and the FLIs 150 between the first surface 170-1 of the die 114 and the package substrate 102. The heater traces 116 may be arranged such that, when power is applied to the heater traces 116, the heater traces 116 generate heat that may be conducted throughout the die 114. In some embodiments, the device layer 124 and/or the layer 122 may be omitted (e.g., when the die 114 is passive), such that the heater traces 116 may heat the die 114 and microelectronic component 103. In some embodiments, the silicon substrate 120 may be omitted, (e.g., such that the layer 122 is at the first surface 170-1 of the die 114) and the package substrate 102 may be coupled to the layer 122 at the first surface 170-1 of the die 114. In such embodiments, the silicon substrate 120 may be removed using any suitable technique, including, for example, mechanical grinding.

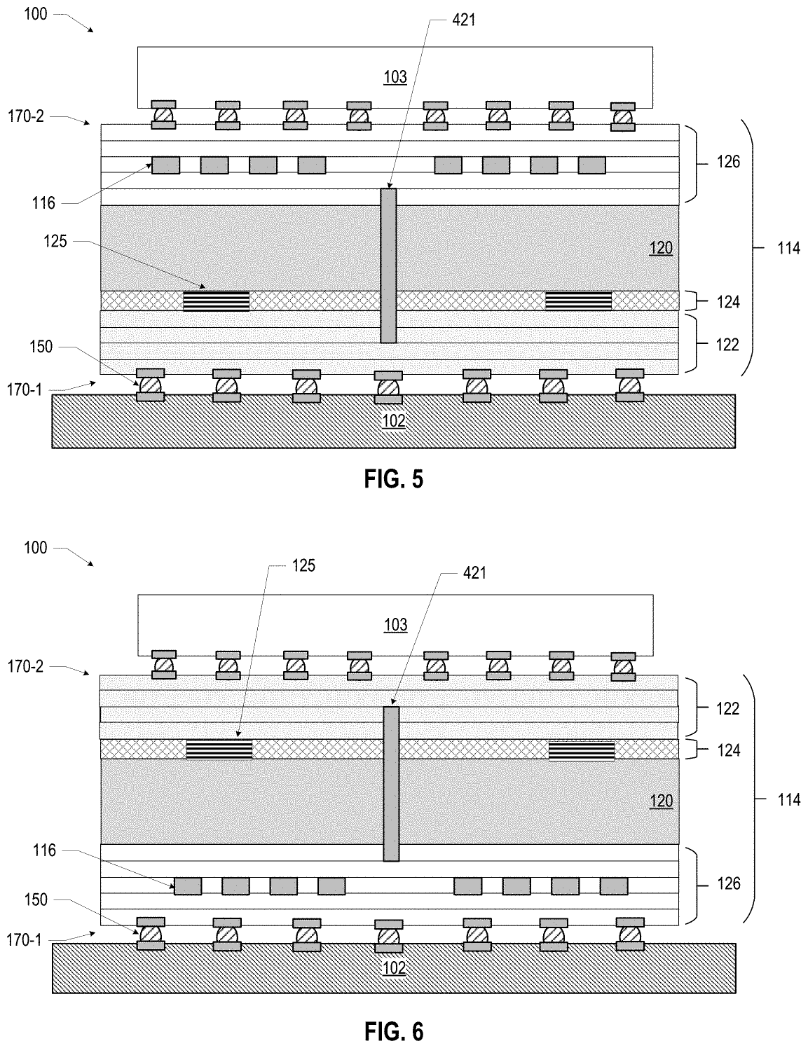

FIG. 5 is a side, cross-sectional view of another example microelectronic assembly, in accordance with various embodiments. The microelectronic assembly 100 may include a die 114 having a backside PDN configuration that includes a layer 122 at a first surface 170-1, a device layer 124 on the layer 122, a silicon substrate 120 on the device layer 124, and a backside-BEOL 126 on the silicon substrate 120. The backside PDN of the die 114 may include one or more heater traces 116 on the backside-BEOL 126 to provide heat to the die 114 for operation within a desired temperature range and/or to provide heat to the devices 125 within the device layer 124. The die 114 may be coupled to a package substrate 102 at the first surface 170-1 and coupled to a microelectronic component 103 at the second surface 170-2 (i.e., at the backside-BEOL 126). The microelectronic assembly 100 may further include a TSV 421 coupling the backside-BEOL 126 to the layer 122. The heater traces 116 may be coupled to a power source (not shown) in the package substrate 102 via the TSV 421 and the FLIs 150 between the first surface 170-1 of the die 114 and the package substrate 102. The heater traces 116 may be arranged such that, when power is applied to the heater traces 116, the heater traces 116 generate heat that may be conducted throughout the die 114. In some embodiments, the device layer 124 and/or the layer 122 may be omitted (e.g., when the die 114 is passive), such that the heater traces 116 may heat the die 114 and microelectronic component 103. In some embodiments, the silicon substrate 120 may be omitted. In such embodiments, the silicon substrate 120 may be removed using any suitable technique, including, for example, mechanical grinding.

FIG. 6 is a side, cross-sectional view of another microelectronic assembly 100, in accordance with various embodiments. The microelectronic assembly 100 may include a die 114 having a backside PDN configuration that includes a backside-BEOL 126 at a first surface 170-1, a silicon substrate 120 on the backside-BEOL 126, a device layer 124 on the silicon substrate, and a layer 122 on the device layer 124. The backside PDN of the die 114 may include a backside-BEOL 126 having one or more heater traces 116 to provide heat to the die 114 for operation within a desired temperature range and/or to provide heat to the devices 125 on the device layer 124. The die 114 may be coupled to a package substrate 102 at a first surface 170-1 and coupled to a microelectronic component 103 at a second surface 170-2 (i.e., at the layer 122). The microelectronic assembly 100 may further include a TSV 421 coupling the backside-BEOL 126 to the layer 122. The heater traces 116 may be coupled to a power source (not shown) in the package substrate 102 via FLIs 150 between the first surface 170-1 of the die 114 and the package substrate 102. The heater traces 116 may be arranged such that, when power is applied to the heater traces 116, the heater traces 116 generate heat that may be conducted throughout the die 114. In some embodiments, the device layer 124 and/or the layer 122 may be omitted (e.g., when the die 114 is passive), such that the heater traces 116 may heat the die 114 and microelectronic component 103. In some embodiments, the silicon substrate 120 may be omitted. In such embodiments, the silicon substrate 120 may be removed using any suitable technique, including, for example, mechanical grinding.

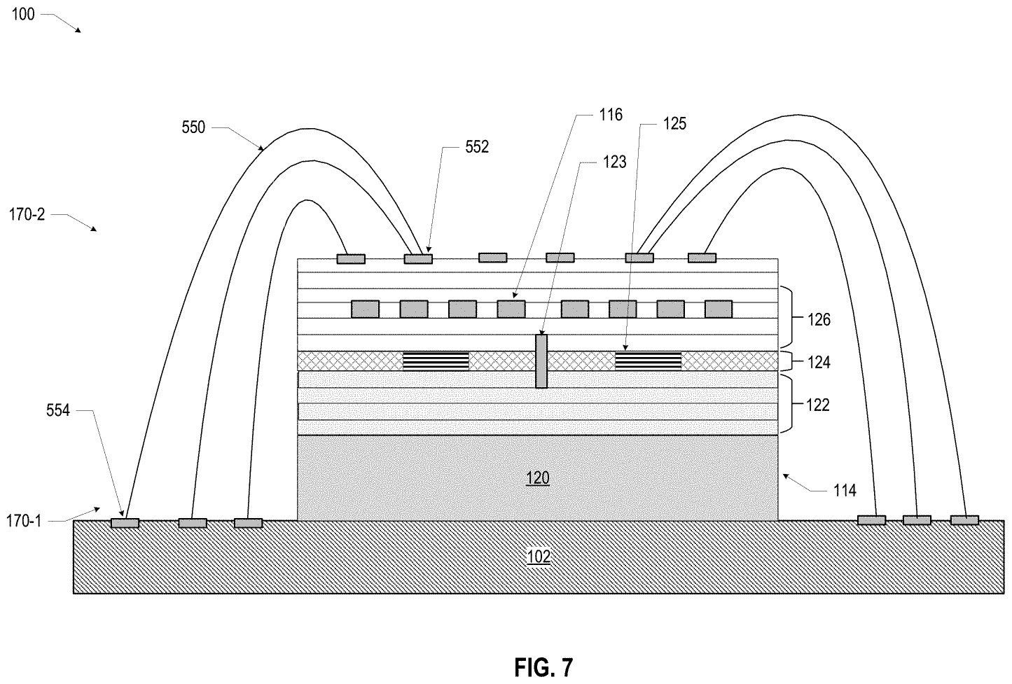

FIG. 7 is a side, cross-sectional view of another example microelectronic assembly, in accordance with various embodiments. The microelectronic assembly 100 may include a die 114 having a backside PDN configuration that includes a silicon substrate 120 at a first surface 170-1, a layer 122 on the silicon substrate 120, a device layer 124 on the layer 122, and a backside-BEOL 126 on the device layer 124. The backside PDN of the die 114 may include one or more heater traces 116 on the backside-BEOL 126 to provide heat to the die 114 for operation within a desired temperature range and/or to provide heat to the devices 125 on the device layer 124. The backside PDN may include a μTSV 123. The second surface 170-2 of the die 114 may be coupled to a package substrate 102 at the first surface 170-1 via wire bonds 550 (e.g., conductive contacts 552 on the second surface of the die 114 are wire bonded 550 to conductive contacts 554 on the surface of the package substrate 102). The heater traces 116 may be coupled to a power source (not shown) in the package substrate 102 via the wire bonds 550. The heater traces 116 may be arranged such that, when power is applied to the heater traces 116, the heater traces 116 generate heat that may be conducted throughout the die 114. In some embodiments, the silicon substrate 120 may be omitted. In such embodiments, the silicon substrate 120 may be removed using any suitable technique, including, for example, mechanical grinding.

The microelectronic assemblies 100 disclosed herein may be used for any suitable application. For example, in some embodiments, a microelectronic assembly 100 may be used to enable very small form factor voltage regulation for field programmable gate array (FPGA) or processing units (e.g., a central processing unit, a graphics processing unit, a FPGA, a modem, an applications processor, etc.) especially in mobile devices and small form factor devices. In another example, the die 114 in a microelectronic assembly 100 may be a processing device (e.g., a central processing unit, a graphics processing unit, a FPGA, a modem, an applications processor, etc.).

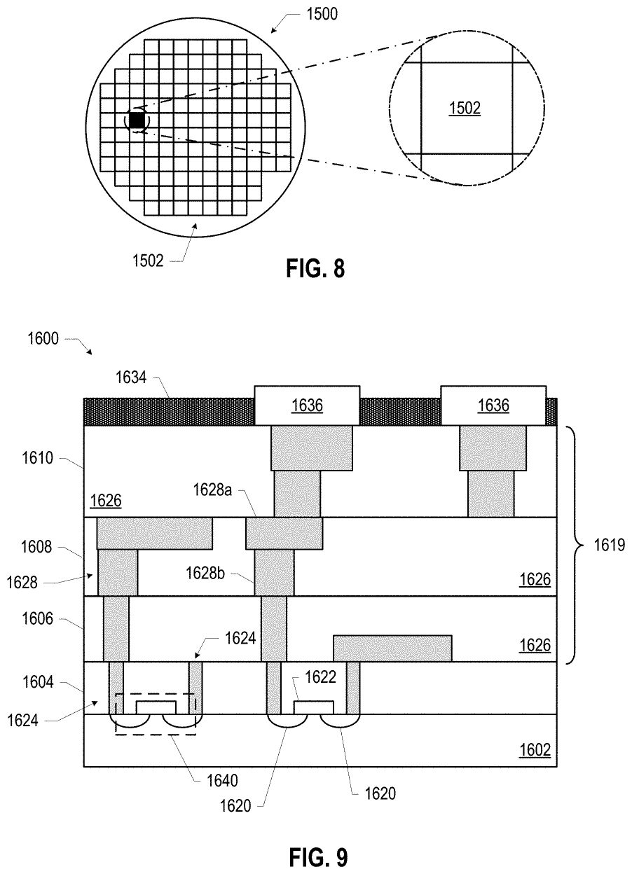

The microelectronic assemblies 100 disclosed herein may be included in any suitable electronic component. FIGS. 8-11 illustrate various examples of apparatuses that may include, or be included in, any of the microelectronic assemblies 100 disclosed herein.

FIG. 8 is a top view of a wafer 1500 and dies 1502 that may be included in any of the microelectronic assemblies 100 disclosed herein (e.g., as any suitable ones of the dies 114 and/or the microelectronic components 103). The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may be any of the dies 114 disclosed herein. The die 1502 may include one or more transistors (e.g., some of the transistors 1640 of FIG. 9, discussed below), supporting circuitry to route electrical signals to the transistors, passive components (e.g., signal traces, resistors, capacitors, or inductors), and/or any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array. In some embodiments, a die 1502 (e.g., a die 114) may be a central processing unit, a radio frequency chip, a power converter, or a network processor. Various ones of the microelectronic assemblies 100 disclosed herein may be manufactured using a die-to-wafer assembly technique in which some dies 114 are attached to a wafer 1500 that include others of the dies 114, and the wafer 1500 is subsequently singulated.

FIG. 9 is a cross-sectional side view of an IC device 1600 that may be included in any of the microelectronic assemblies 100 disclosed herein (e.g., in any of the dies 114). One or more of the IC devices 1600 may be included in one or more dies 1502 (FIG. 8). The IC device 1600 may be formed on a die substrate 1602 (e.g., the wafer 1500 of FIG. 8) and may be included in a die (e.g., the die 1502 of FIG. 8). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 8) or a wafer (e.g., the wafer 1500 of FIG. 8).

The IC device 1600 may include one or more device layers 1604 disposed on the die substrate 1602. The device layer 1604 may include features of one or more transistors 1640 (e.g., metal oxide semiconductor field-effect transistors (MOSFETs)) formed on the die substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a PMOS or a NMOS transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 9 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs; in particular, the arrangement is not limited to the particular configuration of interconnect structures 1628 depicted in FIG. 9. Although a particular number of interconnect layers 1606-1610 is depicted in FIG. 9, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page from the perspective of FIG. 9. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 9. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 9, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

In some embodiments in which the IC device 1600 is a double-sided die (e.g., like the die 114-1), the IC device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the IC device 1600 from the conductive contacts 1636.

In other embodiments in which the IC device 1600 is a double-sided die (e.g., like the die 114-1), the IC device 1600 may include one or more TSVs through the die substrate 1602; these TSVs may make contact with the device layer(s) 1604, and may provide conductive pathways between the device layer(s) 1604 and additional conductive contacts (not shown) on the opposite side of the IC device 1600 from the conductive contacts 1636.

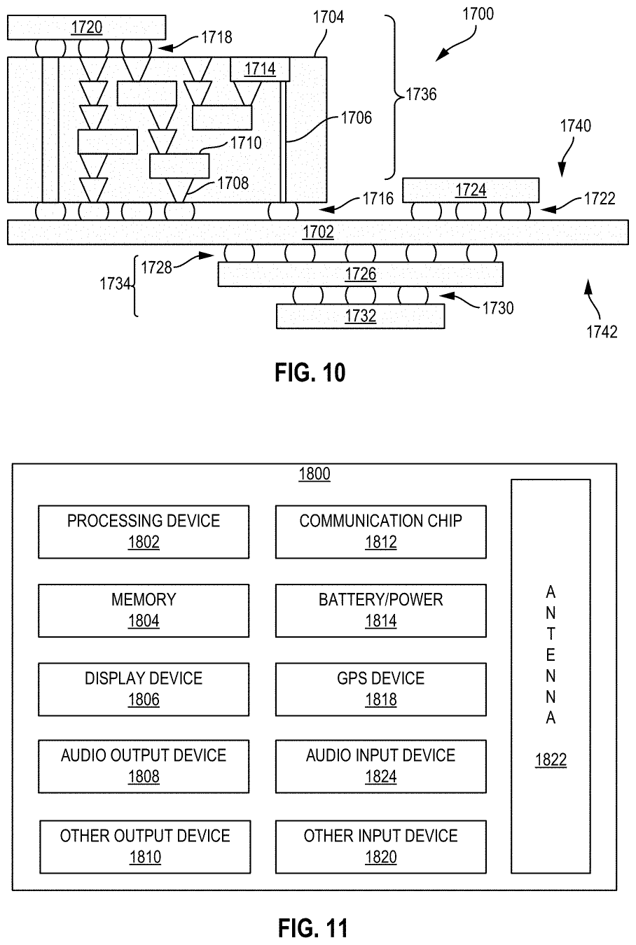

FIG. 10 is a cross-sectional side view of an IC device assembly 1700 that may include any of the microelectronic assemblies 100 disclosed herein. In some embodiments, the IC device assembly 1700 may be a microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies 100 disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 10), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 8), an IC device (e.g., the IC device 1600 of FIG. 9), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 10, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example electrical device 1800 that may include one or more of the microelectronic assemblies 100 disclosed herein. For example, any suitable ones of the components of the electrical device 1800 may include one or more of the IC device assemblies 1700, IC devices 1600, or dies 1502 disclosed herein, and may be arranged in any of the microelectronic assemblies 100 disclosed herein. A number of components are illustrated in FIG. 11 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 11, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-M RAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a hand-held, portable or mobile computing device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

The following paragraphs provide various examples of the embodiments disclosed herein.

Example 1 is a microelectronic assembly, including a package substrate; and a die, electrically coupled to the package substrate, the die including a silicon substrate having a first surface and an opposing second surface; a device layer at the first surface of the silicon substrate; and a dielectric layer, including a heater trace, at the second surface of the silicon substrate.

Example 2 may include the subject matter of Example 1, and may further specify that the heater trace is a first heater trace, and that the dielectric layer further includes a second heater trace.

Example 3 may include the subject matter of Example 2, and may further specify that the dielectric layer includes a plurality of layers, and that the first heater trace and the second heater trace are on a same layer in the dielectric layer.

Example 4 may include the subject matter of Example 2, and may further specify that the dielectric layer includes a plurality of layers, and that the first heater trace and the second heater trace are on different layers in the dielectric layer.

Example 5 may include the subject matter of Example 1, and may further include a power source on the package substrate, wherein the heater trace is electrically coupled to the power source.

Example 6 may include the subject matter of Example 2, and may further include a first power source on the package substrate, wherein the first heater trace is electrically coupled to the first power source; and a second power source on the package substrate, wherein the second heater trace is electrically coupled to the second power source.

Example 7 may include the subject matter of Example 1, and may further specify that a device in the device layer is proximate to the heater trace.

Example 8 may include the subject matter of Example 7, and may further specify that the device is a transistor.

Example 9 may include the subject matter of Example 1, and may further include a heater control device on the package substrate and coupled to the heater trace by conductive pathways in the package substrate.

Example 9B may include the subject matter of Example 1, and may further specify that the dielectric layer is a first dielectric layer, that the device layer has a first surface and an opposing second surface, that the second surface of the device layer is at the first surface of the silicon substrate, and further including a second dielectric layer at the first surface of the device layer.

Example 10 is an integrated circuit (IC) die, including a first dielectric layer including a heater trace; a device layer on the first dielectric layer; and a second dielectric layer on the device layer.

Example 11 may include the subject matter of Example 10, and may further specify that a pattern of the heater trace includes serpentine, spiral, block spiral, zigzag, or linear.

Example 12 may include the subject matter of Example 11, and may further specify that a material of the heater trace includes copper.

Example 13 may include the subject matter of Example 10, and may further include a temperature sensor trace in the first dielectric layer.

Example 14 may include the subject matter of Example 13, and may further specify that a material of the temperature sensor trace includes a metal.

Example 15 may include the subject matter of Example 10, and may further include a silicon substrate between the first dielectric layer and the device layer.

Example 16 is a computing device, including a package substrate having a power source; and a die, having a first surface and an opposing second surface, including a first dielectric layer at the first surface of the die; a device layer on the first dielectric layer; a substrate layer on the device layer; and a second dielectric layer on the substrate layer, the second dielectric layer having a heater trace electrically coupled to the power source on the package substrate.

Example 17 may include the subject matter of Example 16, and may further specify that a device in the device layer is a transistor.

Example 18 may include the subject matter of Example 16, and may further include a temperature sensor trace in the second dielectric layer.

Example 19 may include the subject matter of Example 16, and may further include a heater control device coupled to the heater trace.

Example 20 may include the subject matter of Example 16, and may further specify that the first dielectric layer further includes first conductive pathways, wherein the second dielectric layer further includes second conductive pathways, and may further include a through-substrate via (TSV) electrically coupling the first and second conductive pathways.

Example 21 may include the subject matter of Example 16, and may further include a microelectronic component coupled to the second dielectric layer of the die.

1. A microelectronic assembly, comprising:
a package substrate; and
a die electrically coupled to the package substrate, the die including:
a silicon substrate having a first surface and an opposing second surface;
a device layer at the first surface of the silicon substrate; and
a dielectric layer, including a heater trace, at the second surface of the silicon substrate.

2. The microelectronic assembly of claim 1, wherein the heater trace is a first heater trace, and further comprising:
a second heater trace in the dielectric layer.

3. The microelectronic assembly of claim 2, wherein the dielectric layer includes a plurality of layers, and wherein the first heater trace and the second heater trace are on a same layer in the dielectric layer.

4. The microelectronic assembly of claim 2, wherein the dielectric layer includes a plurality of layers, and wherein the first heater trace and the second heater trace are on different layers in the dielectric layer.

5. The microelectronic assembly of claim 1, further comprising:
a power source on the package substrate, wherein the heater trace is electrically coupled to the power source.

6. The microelectronic assembly of claim 2, further comprising:
a first power source on the package substrate, wherein the first heater trace is electrically coupled to the first power source; and
a second power source on the package substrate, wherein the second heater trace is electrically coupled to the second power source.

7. The microelectronic assembly of claim 1, wherein a device in the device layer is proximate to the heater trace.

8. The microelectronic assembly of claim 7, wherein the device is a transistor.

9. The microelectronic assembly of claim 1, further comprising:
a heater control device on the package substrate and coupled to the heater trace by conductive pathways in the package substrate.

10. An integrated circuit (IC) die, comprising:
a first dielectric layer including a heater trace;
a device layer on the first dielectric layer; and
a second dielectric layer on the device layer.

11. The IC die of claim 10, wherein a pattern of the heater trace includes serpentine, spiral, block spiral, zigzag, or linear.

12. The IC die of claim 11, wherein a material of the heater trace includes copper.

13. The IC die of claim 10, further comprising:
a temperature sensor trace in the first dielectric layer.

14. The IC die of claim 13, wherein a material of the temperature sensor trace includes a metal.

15. The IC die of claim 10, further comprising:
a silicon substrate between the first dielectric layer and the device layer.

16. A computing device, comprising:
a package substrate having a power source; and
a die, having a first surface and an opposing second surface, including:
a first dielectric layer at the first surface of the die;
a device layer on the first dielectric layer;
a substrate layer on the device layer; and
a second dielectric layer on the substrate layer, the second dielectric layer having a heater trace electrically coupled to the power source on the package substrate.

17. The computing device of claim 16, wherein a device in the device layer is a transistor.

18. The computing device of claim 16, further comprising:
a temperature sensor trace in the second dielectric layer.

19. The computing device of claim 16, further comprising:
a heater control device coupled to the heater trace.

20. The computing device of claim 16, wherein the first dielectric layer further includes first conductive pathways, wherein the second dielectric layer further includes second conductive pathways, and further comprising:
a through-substrate via (TSV) electrically coupling the first and second conductive pathways.
